(19) United States
(12) Patent Application Publication
(10) Pub. No.: US 2015/0318052 A1
(43) Pub. Date: Nov. 5, 2015

(54) SHIFT REGISTER UNIT, GATE DRIVE CIRCUIT AND DISPLAY DEVICE

(71) Applicants: BOE TECHNOLOGY GROUP CO., LTD., Beijing (CN); BEIJING BOE OPTOELECTRONICS TECHNOLOGY CO., LTD., Beijing (CN)

(72) Inventor: Jinyu LI, Beijing (CN)

(21) Appl. No.: 14/488,624

(22) Filed: Sep. 17, 2014

(30) Foreign Application Priority Data
Apr. 30, 2014 (CN) 201410183457.0

(51) Int. Cl. G11C 19/28

(52) U.S. Cl. CPC G11C 19/28

(57) ABSTRACT

According to this disclosure, a shift register unit includes a pull-up control module, a pull-up module, a pull-down control module and a pull-down module, wherein the pull-up module is adapted to provide a transmission signal output terminal with a first clock signal inputted from a first clock signal input terminal according to the pull-up control signal, and provide a gate drive signal output terminal with a first direct current supply voltage according to the pull-up control signal and the first clock signal inputted from the first clock signal input terminal.

### CROSS-REFERENCE TO RELATED APPLICATION

The present application claims a priority of the Chinese patent application No. 201410183457.0 filed on Apr. 30, 2014, which is incorporated herein by reference in its entirety.

### TECHNICAL FIELD

The present disclosure relates to the field of display technology, and in particular to a shift register unit, a gate drive circuit and a display device.

### BACKGROUND

A schematic circuit diagram of a shift register unit in the prior art is shown in FIG. 1. The shift register unit includes a pull-up control module consisting of a first transistor M1, a pull-up module consisting of a third transistor M3 and a capacitor C, a pull-down module consisting of a second transistor M2, a fourth transistor M4, a tenth transistor M10 and an eleventh transistor M11, and a pull-down control module consisting of a fifth transistor M5, a sixth transistor M6, a ninth transistor M9 and an eighth transistor M8. A signal (INPUT) is inputted from a signal input terminal, a first clock signal (CLK) is inputted from a first clock signal input terminal, a second clock signal (CLKB) is inputted from a second clock signal input terminal, a low-voltage signal (VSS) is inputted from a low-voltage signal input terminal, a reset signal (RESET) is inputted from a reset signal input terminal, and a gate drive signal (OUTPUT) is outputted from a signal output terminal. A crossing point between a drain electrode of the first transistor M1, a source electrode of the second transistor M2, a gate electrode of the third transistor M3, a gate electrode of the eighth transistor M8, a gate electrode of the sixth transistor M6, and a first electrode of the capacitor C1 is defined as a pull-up node (PU). A crossing point between a drain electrode of the fifth transistor M5, a source electrode of the sixth transistor M6, a gate electrode of the tenth transistor M10 and a gate electrode of the eleventh transistor M11 is defined as a pull-down node (PD). And a crossing point between a drain electrode of the eighth transistor M8, a source electrode of the ninth transistor M9 and a gate electrode of the fifth transistor M5 is defined as a pull-down control node (PD_CN).

The above shift register circuit can achieve the shift function. However, in an aspect, a gate drive signal is provided to the gate drive signal output terminal by the pull-up module according to the first clock signal CLK with alternate high and low levels (i.e., the first clock signal CLK is taken as the input signal for the third transistor M3 outputting the gate drive signal); and in another aspect, in the case where the gate drive signal is also taken as the signal to be inputted to the next shift register (i.e., the transmission signal), the third transistor M3 in the pull-up module needs to be designed relatively large (with a channel width of appropriate 8100 μm), then the parasitic capacitance generated by the third transistor M3 (especially the gate-drain parasitic capacitance Cgd) is relatively high. And the third transistor M3 is charged and discharged frequently due to the existence of the capacitive coupling effect caused by frequent switching thereof between a high level and a low level, so that the third transistor M3 has high power loss, thus the power consumption of the shift register unit is increased, and then finally the power consumption of the liquid crystal display in which the shift register unit is adopted is increased.

### SUMMARY

It is provided a shift register unit, a gate drive circuit and a display device in an embodiment of the disclosure, for solving the problem in the prior art that the power consumption of the shift register unit is relatively high since the clock signal is taken as the input signal for the output means of the shift register unit.

Specific technical solutions provided in the embodiments of the disclosure are as follows.

A shift register unit includes a pull-up control module, a pull-up module, a pull-down control module and a pull-down module, wherein

the pull-up control module is adapted to output a pull-up control signal to a pull-up node according to a transmission signal inputted from a transmission signal input terminal, the pull-up node is on a wire connecting the pull-up control module and the pull-up module;

the pull-up module is adapted to provide a transmission signal output terminal with a first clock signal input from a first clock signal input terminal according to the pull-up control signal, and provide a gate drive signal output terminal with a first direct current supply voltage according to the pull-up control signal and the first clock signal;

the pull-down control module is adapted to output a pull-down control signal to a pull-down node according to the first clock signal, the pull-down node is on a wire connecting the pull-down control module and the pull-down module; and

the pull-down module is adapted to provide the pull-up node, the transmission signal output terminal and the gate drive signal output terminal with a second direct current supply voltage according to the pull-down control signal, a reset signal inputted from a reset signal input terminal and a second clock signal inputted from a second clock signal input terminal; and the first clock signal inputted from the first clock signal input terminal is opposite to the second clock signal input from the second clock signal input terminal in phase.

A gate drive circuit includes the shift register unit described above; wherein except for a first shift register unit and a last shift register unit, each shift register unit has its transmission signal output terminal connected to the reset signal input terminal of a previous shift register unit adjacent to this shift register unit and the transmission signal input terminal of a next shift register unit adjacent to this shift register unit, gate drive signals outputted from the gate drive signal output terminals of the shift register units are outputted from the gate drive circuit in sequence;

the transmission signal output terminal of the first shift register unit is connected to a transmission signal input terminal of a second shift register unit, the transmission signal output terminal of the last shift register unit is connected to the reset signal input terminal of a previous shift register unit adjacent to the last shift register unit; and

a frame start signal is inputted from the transmission signal input terminal of the first shift register unit.

A display device includes the gate drive circuit described above.

With the embodiments of the disclosure, the pull-up module takes the first direct current supply voltage as the source of the gate drive signal, and outputs the gate drive signal and the transmission signal through different terminals, so that the transistor adapted to output the gate drive signal in the pull-up module has no capacitive coupling effect, and the resulting parasitic capacitor will not be charged and discharged frequently (the first direct current supply voltage is not switched between the high level and the low level), thus the transistor for outputting the gate drive signal will not lose massive power due to the frequent charging and discharging, and the problem of increased power consumption of the shift register unit due to the high power consumption of the transistor for outputting the gate drive signal is solved.

### BRIEF DESCRIPTION OF THE DRAWINGS

FIG. 1 is a circuit diagram of a shift register unit according to the prior art;

FIG. 2 is a schematic structural diagram of a shift register unit according to a first embodiment of the disclosure;

FIG. 3 is a schematic circuit diagram of a shift register unit according to a second embodiment of the disclosure;

FIG. 4 is a schematic circuit diagram of another shift register unit according to the second embodiment of the disclosure;

FIG. 5 is a sequency chart of the shift register unit according to the second embodiment of the disclosure; and

FIG. 6 is a schematic structural diagram of a gate drive circuit according to a third embodiment of the disclosure.

### DETAILED DESCRIPTION

The embodiments of the shift register unit, the gate drive circuit and the display device will be described hereinafter in conjunction with the drawings in the specification.

### First Embodiment

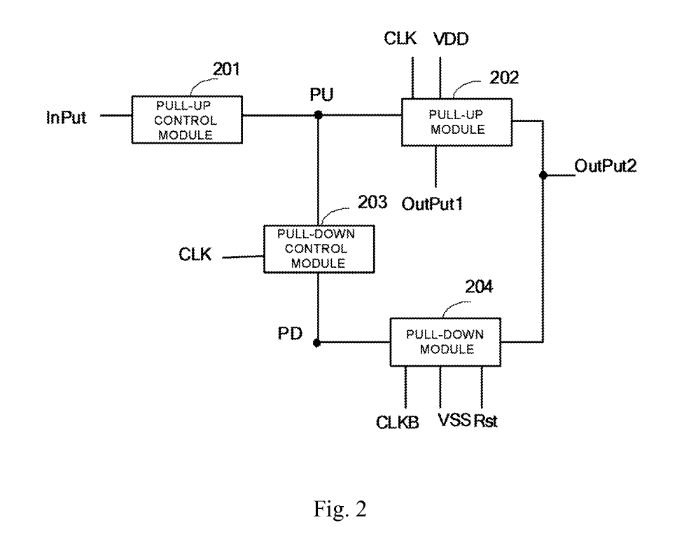

As shown in FIG. 2, which is a schematic structural diagram of a shift register unit according to a first embodiment of the disclosure, the shift register unit includes a pull-up control module 201, a pull-up module 202, a pull-down control module 203 and a pull-down module 204, wherein

the pull-up control module 201 has an input terminal connected to a transmission signal input terminal, and an output terminal connected to a pull-up node, and is adapted to output a pull-up control signal to the PU according to a transmission signal inputted from a transmission signal input terminal, the PU is on a wire connecting the pull-up control module and the pull-up module;

the pull-up module 202 has an input terminal connected to the pull-up node, and an output terminal connected to a gate drive signal output terminal and the transmission signal output terminal, and is adapted to provide a transmission signal output terminal with a first clock signal CLK inputted from a first clock signal input terminal according to the pull-up control signal, and provide a gate drive signal output terminal with a first direct current supply voltage VDD according to the pull-up control signal and the first clock signal inputted from the first clock signal input terminal;

the pull-down control module 203 has an input terminal connected to the pull-up node PU, and an output terminal connected to the pull-down node PD, and is adapted to output a pull-down control signal to a pull-down node PD according to the first clock signal CLK inputted from the first clock signal input terminal, the pull-down node PD is on a wire connecting the pull-down control module and the pull-down module; and

the pull-down module 204 has an input terminal connected to the pull-down node PD, and an output terminal connected to the gate drive signal output terminal, and is adapted to provide the pull-up node, the transmission signal output terminal and the gate drive signal output terminal with a second direct current supply voltage VSS according to the pull-down control signal, a reset signal Rst inputted from a reset signal input terminal and a second clock signal CLKB inputted from a second clock signal input terminal; and the first clock signal inputted from the first clock signal input terminal is opposite to the second clock signal inputted from the second clock signal input terminal in phase.

Preferably, the pull-down module 204 includes a first pull-down sub-module, a second pull-down sub-module and a third pull-down sub-module, and the first pull-down sub-module, the second pull-down sub-module and the third pull-down sub-module have the following two different methods to achieve the function of the pull-down module 204.

### First Method

The first pull-down sub-module is adapted to output the second direct current supply voltage to the pull-up node according to the pull-down control signal and the reset signal;

the second pull-down sub-module is adapted to output the second direct current supply voltage to the gate drive signal output terminal according to the second clock signal inputted from the second clock signal input terminal; and

the third pull-down sub-module is adapted to output the second direct current supply voltage to the transmission signal output terminal according to the second clock signal inputted from the second clock signal input terminal.

### Second Method

The first pull-down sub-module is adapted to output the second direct current supply voltage to the pull-up node according to the pull-down control signal and the reset signal;

the second pull-down sub-module is adapted to output the second direct current supply voltage to the gate drive signal output terminal according to the second clock signal inputted from the second clock signal input terminal and the reset signal; and

the third pull-down sub-module is adapted to output the second direct current supply voltage to the transmission signal output terminal according to the second clock signal inputted from the second clock signal input terminal.

With the embodiment of the disclosure, the pull-up module takes the first direct current supply voltage as the source of the gate drive signal, and outputs the gate drive signal and the transmission signal through different terminals, so that the transistor adapted to output the gate drive signal in the pull-up module has no capacitive coupling effect, and the resulting parasitic capacitor will not be charged and discharged frequently (the first direct current supply voltage is not switched between the high level and the low level), thus the transistor for outputting the gate drive signal will not lose massive power due to the frequent charging and discharging, and the problem of increased power consumption of the shift register unit due to the high power consumption of the transistor for outputting the gate drive signal can be solved.

The solution of the first embodiment of the disclosure will be further described in a second embodiment.

### Second Embodiment

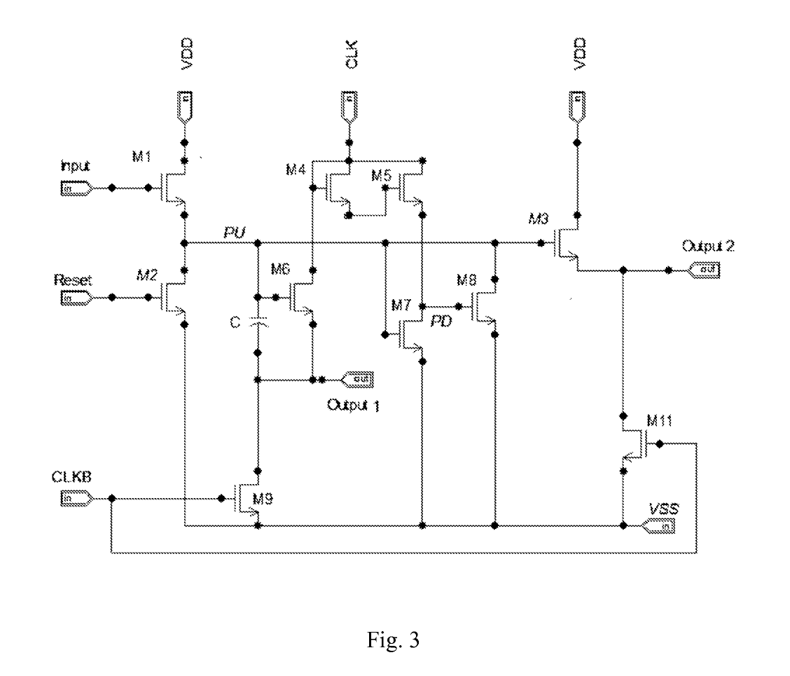

A schematic circuit diagram of a shift register unit according to a second embodiment of the disclosure is shown in FIG. 3.

The signals inputted into the shift register unit include: a first clock signal CLK, a second clock signal CLKB, a transmission signal InPut, a reset signal Reset, a first direct current supply voltage VDD (which is always a high-level signal) and a second direct current supply voltage VSS (which is always a low-level signal). And the signals outputted from the shift register unit include a transmission signal Output1 and a gate drive signal Output2.

Further, the pull-up module 202 consists of a capacitor C, a sixth transistor M6, and a third transistor M3.

The first pull-down sub-module in the first method in the first embodiment consists of a second transistor M2 and an eighth transistor M8.

The second pull-down sub-module in the first method in the first embodiment consists of an eleventh transistor M11.

The third pull-down sub-module in the first method in the first embodiment consists of a ninth transistor M9.

The pull-down control module 203 consists of a fourth transistor M4, a fifth transistor M5 and a seventh transistor M7.

The pull-up control module 201 consists of a first transistor M1.

The connection relations between the above transistors and capacitors are as follows.

The capacitor C has a first electrode connected to the pull-up node, and a second electrode connected to the transmission signal output terminal;

the sixth transistor M6 has a gate electrode connected to the pull-up node, a source electrode connected to the first clock signal input terminal, and a drain electrode connected to the transmission signal output terminal; and

the third transistor M3 has a gate electrode connected to the pull-up node, a source electrode connected to the first direct current supply voltage, and a drain electrode connected to the gate drive signal output terminal.

The second transistor M2 has a gate electrode connected to the reset signal input terminal, a source electrode connected to the pull-up node, and a drain electrode connected to the second direct current supply voltage;

the eighth transistor M8 has a gate electrode connected to the pull-down node, a source electrode connected to the pull-up node, and a drain electrode connected to the second direct current supply voltage;

the eleventh transistor M11 has a gate electrode connected to the second clock signal input terminal, a source electrode connected to the gate drive signal output terminal, and a drain electrode connected to the second direct current supply voltage; and

the ninth transistor M9 has a gate electrode connected to the second clock signal input terminal, a source electrode connected to the transmission signal output terminal, and a drain electrode connected to the second direct current supply voltage;

the fourth transistor M4 has a gate electrode connected to the first clock signal input terminal, a source electrode connected to the first clock signal input terminal, and a drain electrode connected to the gate electrode of a fifth transistor;

the fifth transistor M5 has a source electrode connected to the first clock signal input terminal, and a drain electrode connected to the pull-down node; and

the seventh transistor M7 has a gate electrode connected to the pull-up node, a source electrode connected to the pull-down node, and a drain electrode connected to the second direct current supply voltage.

The first transistor M1 has a gate electrode connected to the transmission signal input terminal, a source electrode connected to the first direct current supply voltage, and a drain electrode connected to the pull-up node.

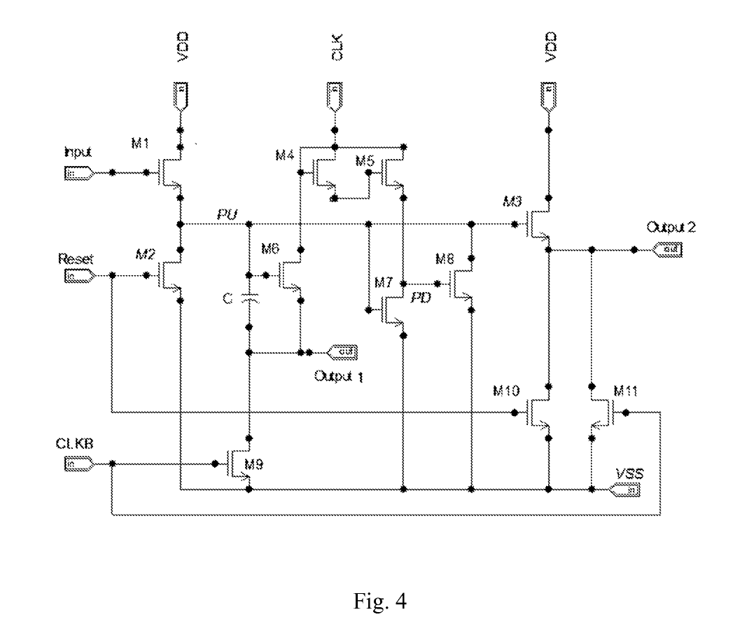

Another schematic circuit diagram of the shift register unit according to the second embodiment of the disclosure is shown in FIG. 4. The difference from FIG. 3 is that a tenth transistor M10 is added. Except for the tenth transistor M10, the connection relations between the transistors and the capacitors are the same as that in FIG. 3, and the first pull-down sub-module in the second method in the first embodiment consists of the second transistor M2 and the eighth transistor M8; the second pull-down sub-module in the second method in the first embodiment consists of the tenth transistor M10 and the eleventh transistor M11; and the third pull-down sub-module in the second method in the first embodiment consists of the ninth transistor M9; and

the tenth transistor M10 has a gate electrode connected to the reset signal input terminal, a source electrode connected to the gate drive signal output terminal, and a drain electrode connected to the second direct current supply voltage.

In the second embodiment of the disclosure, the first direct current supply voltage VDD is taken as the input signal for the third transistor M3, so that frequent charging and discharging of the third transistor M3 is avoided, and then the power consumption caused by the register is reduced significantly.

Further, in the large-scale liquid crystal display, the transistor of the shift register has a relatively large size, especially the third transistor M3. The larger the third transistor M3, the higher the power consumption under the function of the first clock signal CLK with alternate high and low levels. By taking the first direct current supply voltage as the input signal for the third transistor M3, the larger the size of the third transistor M3, the more significant the reduction of the power consumption.

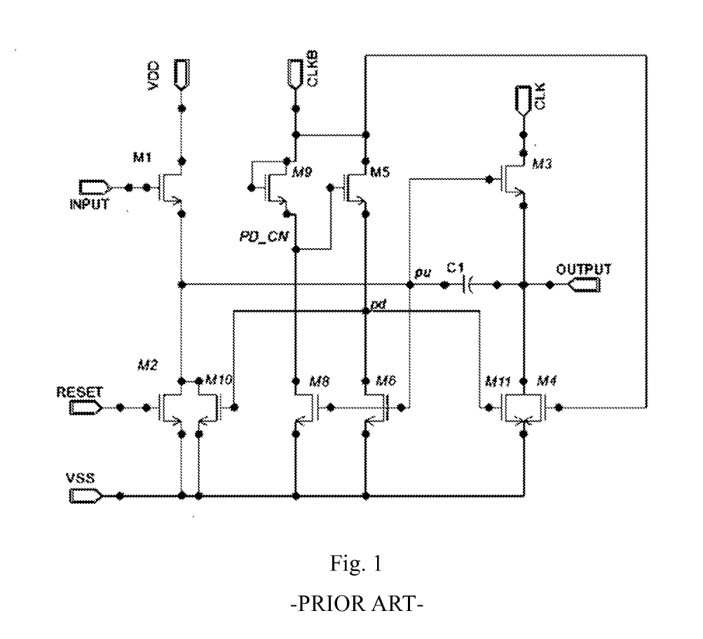

To obtain a specific comparison result, the structure of the single stage of shift register is simulated using a simulation software. In the case where the transistors in the embodiment of the disclosure have the same size as the corresponding transistor in the shift register shown in FIG. 1, a sum of the current on the signal line of the shift register unit shown in FIG. 1 is 34.9 μA, and a sum of the current on all the signal lines in the second embodiment of the disclosure is 12.3 μA, which is only about ⅓ of that of the shift register unit shown in FIG. 1. It can be seen that the current in the circuit can be reduced significantly in the disclosure, for reducing the power consumption.

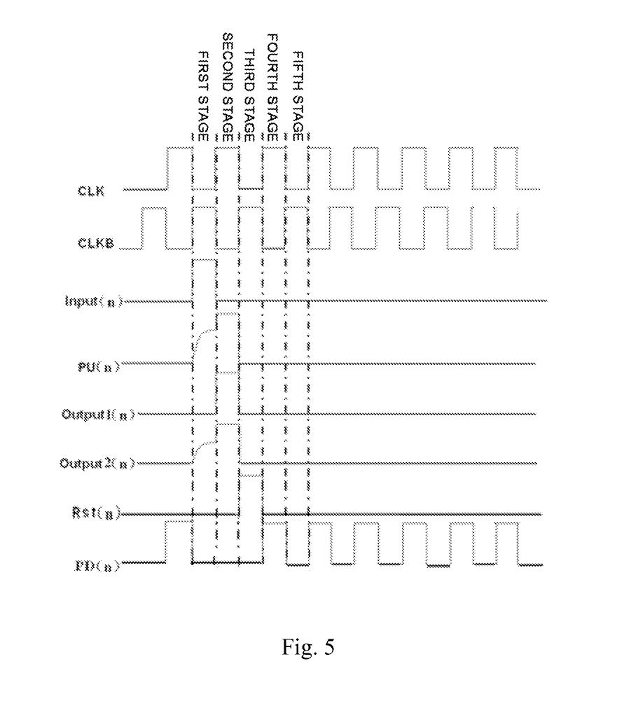

To further describe the working principle of the second embodiment of the disclosure, the description will be given by taking the circuit of the shift register unit shown in FIG. 3 as an example in conjunction with the scan sequence chart shown in FIG. 5.

A scan sequence chart of the shift register unit according to the second embodiment of the disclosure is shown in FIG. 5.

Specifically, CLK is the first clock signal inputted into the shift register unit S/R(n);

CLKB is the second clock signal inputted into the shift register unit S/R(n);

InPut(n) is the transmission signal outputted from the transmission signal output terminal of the previous shift register unit S/R(n−1) of the shift register unit S/R(n), and is taken as the transmission signal inputted from the transmission signal input terminal of the shift register unit S/R(n);

PU(n) is the pull-up control signal outputted from the pull-up control module of the shift register unit S/R(n);

PD(n) is the pull-down control signal outputted from the pull-down control module of the shift register unit S/R(n);

Rst(n) is the transmission signal outputted from the transmission signal output terminal of the next shift register unit S/R(n+1) of the shift register unit S/R(n), and is taken as the reset signal inputted from the reset signal input terminal of the shift register unit S/R(n);

OutPut1(n) is the transmission signal outputted from the transmission signal output terminal of the shift register unit S/R(n);

OutPut2(n) is the gate drive signal outputted from the gate drive signal output terminal of the shift register unit S/R(n);

VDD is the first direct current supply voltage inputted into the shift register unit S/R(n), and is a high-level signal; and

VSS is the second direct current supply voltage inputted into the shift register unit S/R(n), and is a low-level signal.

The scan timing process of the shift register unit S/R(n) can be divided into five stages (the first stage, the second stage, the third stage, the fourth stage and the fifth stage in FIG. 5 indicate the time periods of the five stages respectively).

In the first stage, i.e., the first half cycle of the first clock cycle, the high-level signal outputted from the transmission signal output terminal of S/R(n−1) is received by the shift register unit S/R(n), i.e., the InPut(n) signal inputted into the transmission signal input terminal of S/R(n) during this stage is a high-level signal; the first clock signal CLK is in low level; the pull-down node PD is in low level, the first transistor M1 is ON, the capacitor C is charged, the level of the pull-up node PU is raised, the seventh transistor M7 is ON, the sixth transistor M6 is ON, the low-level signal of the first clock signal CLK is outputted from the transmission signal output terminal, the transmission signal OutPut1(n) output at this time is a low-level signal; further, the level of the pull-up node PU is raised, the third transistor M3 is also ON, the current between the source electrode and the drain electrode of the third transistor M3 is increased gradually, and the voltage of OutPut2(n) starts to go up. Since CLKB during this stage is a high-level signal, the ninth transistor M9 and the eleventh transistor M11 are ON, the conduction of the ninth transistor M9 can stabilize the outputting of the transmission signal OutPut1(n), for preventing the transmission signal OutPut1(n) from being raised due to the coupling effect of the capacitor C. The conduction of the eleventh transistor M11 will pull down the voltage of the gate drive signal Output2(n) to some extent, but the pull-down capability of the eleventh transistor M11 is inferior to the pull-down capability of the third transistor M3 due to the size difference between the third transistor M3 and the eleventh transistor M11 (M3>>M11), the gate drive signal OutPut2(n) can not be pulled down to the second supply voltage VSS completely, and the gate drive signal Output2(n) is still outputted.

In the second stage, i.e., the last haft cycle of the first clock cycle, the transmission signal input into S/R(n) is a low-level signal (i.e., the InPut(n) is a low-level signal during this stage), the second clock signal CLKB is in low level; the first clock signal CLK is in high level; the pull-down node PD is in low level, the sixth transistor M6 is still ON, the first clock signal CLK in high level connected to the source electrode of the sixth transistor M6 is outputted from the sixth transistor M6 to the transmission signal output terminal, the transmission signal OutPut1(n) output at this time is a high-level signal; further, due to the bootstrap effect of the capacitor C, the level of the pull-up node PU is continuously raised, the third transistor M3 is completely ON, and the first direct current supply voltage VDD connected to the source electrode of the third transistor M3 is outputted to the gate drive signal output terminal, i.e., OutPut2(n) is a high-level signal.

It can been seen from the above description of the first stage and the second stage and the gate drive signal OutPut2(n) shown in FIG. 5 that the voltage outputted by the gate drive signal OutPut2(n) during these two stages is step-shaped. When the shift register unit is applied in the liquid crystal panel, if the signal inversion method adopts column inversion during the display of the liquid crystal panel, the Data signals in two adjacent rows have the same polarity, i.e., both being “+” or “−”. When a high voltage is outputted from the previous register unit, i.e., working in the third stage, the output of this stage of register unit is just in the second stage, the gate lines connected to the previous shift register unit are completely ON, the pixel is charged, the gate lines connected to this stage of shift register unit are also ON, and the Data in the last row may also be written into this row, i.e., achieving the pre-charging.

In the third stage, i.e., the first half cycle of the second clock cycle, the reset signal inputted into S/R(n) is a high-level signal (i.e., the transmission signal OutPut1(n+1) outputted from the transmission signal output terminal of S/R(n+1) is a high-level signal during this stage), the first clock signal CLK is in low level, the second clock signal CLKB is in high level, the ninth transistor M9, the eleventh transistor M11 and the second transistor M2 each is ON, the level of the pull-up node PU, the transmission signal output terminal and the gate drive signal output terminal each is pulled down, the third transistor M3 is OFF, the sixth transistor M6 and the seventh transistor M7 each is OFF, the pull-down node PD keeps in low level, the transmission signal OutPut1(n) outputted from the transmission signal output terminal is a low-level signal, and the signal OutPut2(n) outputted from the gate drive signal output terminal is a low-level signal.

In the fourth stage, i.e., the last half cycle of the second clock cycle, the first clock signal CLK is in high level, the second clock signal CLKB is in low level, the reset signal inputted into S/R(n) is a low-level signal, the fourth transistor M4 and the fifth transistor M5 each is ON, the second transistor M2 is OFF, and the seventh transistor M7 maintains OFF, the pull-down node PD is in high level, the eighth transistor M8 is ON, so that the pull-up node PU has the same level as the second direct current supply voltage, keeping low level. At this time, the sixth transistor M6, the seventh transistor M7 and the third transistor M3 still maintains OFF, the transmission signal OutPut1(n) outputted from the transmission signal output terminal is a low level signal, and the signal OutPut2(n) outputted from the gate drive signal output terminal is a low level signal.

In the fifth stage, i.e., the first half cycle of the third clock cycle, the first clock signal CLK is in low level, the second clock signal CLKB is in high level, the reset signal inputted into S/R(n) is a low-level signal, the ninth transistor M9 and the eleventh transistor M11 each is ON, the pull-up node PU keeps in low level, the seventh transistor M7 still maintains OFF, the pull-down node PD has the same level as CLK, the transmission signal OutPut1(n) outputted from the transmission signal output terminal is a low-level signal, and the signal OutPut2(n) outputted from the gate drive signal output terminal is a low-level signal.

Then, the fourth and the fifth stages are repeated sequentially, until the transmission signal InPut(n) inputted into the transmission signal input terminal of the shift register unit S/R(n) becomes a high-level signal, and then the first stage is performed again.

The circuit in FIG. 4 has the same working principle as that in FIG. 3. The gate drive signal outputted from the gate drive signal output terminal is pulled down by the added tenth transistor M10 under the control of the reset signal, thus the tenth transistor M10 is only ON when the reset signal is in high level, and then the tenth transistor M10 together with the eleventh transistor M11 pulls down the gate drive signal outputted from the gate drive signal output terminal.

In FIG. 4, the tenth transistor M10 has greater size (width) than the eleventh transistor M11, for reducing the power consumption. Since the tenth transistor M10 serves to pull down only in the case where next stage of OutPut1(n+1) is in high level, i.e., this stage of reset signal (Rst) is in high level. The eleventh transistor M11 is synchronized with the second clock signal CLKB, i.e., serving to pull down frequently along with the switching of the second clock signal CLKB between the high level and the low level, for further reducing the power consumption of the drive circuit. The tenth transistor M10 should be as large as possible, and the eleventh transistor M11 should be as small as possible. Preferably, the ratio of the channel width of the tenth transistor M10 to the eleventh transistor M11 is 9:1. In the embodiment shown in FIG. 3, the size of the eleventh transistor M11 is a sum of those of the tenth transistor M10 and the eleventh transistor M11 in FIG. 4.

### Third Embodiment

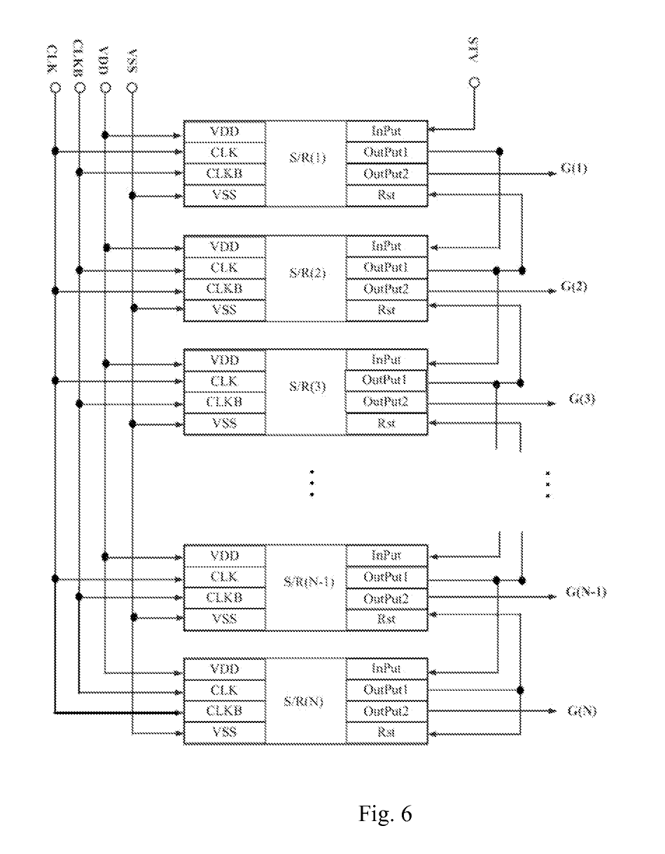

Based on the same conception as that of the first embodiment and the second embodiment of the disclosure, it is provided a gate drive circuit in a third embodiment of the disclosure, the schematic structural diagram of which is shown in FIG. 6. The gate drive circuit includes a plurality of shift register units as described in the first embodiment, e.g., N shift register units, i.e., S/R(1), S/R(2), . . . , S/R(N). Except for a first shift register unit and a last shift register unit, each shift register unit has its transmission signal output terminal connected to the reset signal input terminal of a previous shift register unit adjacent to this shift register unit and the transmission signal input terminal of a next shift register unit adjacent to this shift register unit, gate drive signals from the gate drive signal output terminals of the shift register units are outputted from the gate drive circuit in sequence;

the transmission signal output terminal of the first shift register unit is connected to a transmission signal input terminal of a second shift register unit, the transmission signal output terminal of the last shift register unit is connected to the reset signal input terminal of a previous shift register unit adjacent to the last shift register unit; and

a frame start signal is inputted from the transmission signal input terminal of the first shift register unit.

For the odd-numbered shift register unit, the first clock signal is inputted from the first clock signal input terminal, and the second clock signal is inputted from the second clock signal input terminal;

for the even-numbered shift register unit, the second clock signal is inputted from the first clock signal input terminal, and the first clock signal is inputted from the second clock signal input terminal;

the first direct current supply voltage VDD is inputted into various shift register units through the first direct current supply voltage input terminal;

the second direct current supply voltage VSS is inputted into various shift register units through the second direct current supply voltage input terminal; and

the first clock signal CLK, the second clock signal CLKB, the first direct current supply voltage VDD and the second direct current supply voltage VSS each is a signal for ensuring the normal operation of the shift register units, and the first clock signal CLK is opposite to the second clock signal CLKB in phase.

It is to be noted that G(1) to G(N) in FIG. 6 indicate a gate line 1 to a gate line N respectively.

In the solution of the third embodiment of the disclosure, since the transistors for outputting the gate drive signal in respective shift register units of the gate drive circuit do not have high power consumption with frequent charging and discharging, the problem of increased power consumption of the gate drive circuit due to the high power consumption of the transistor for outputting the gate drive signal can be solved.

### Fourth Embodiment

It is provided a display device in the fourth embodiment of the disclosure, which includes the gate drive circuit described in the third embodiment.

the display device provided in the fourth embodiment of the disclosure comprises but is not limited to at least one of a liquid crystal panel, an electronic paper, a liquid crystal TV, a liquid crystal display (LCD), a digital photo frame, a mobile phone, a tablet computer, and an outdoor display.

Apparently, various modifications and variations can be made to the disclosure by those skilled in the art without deviating from the spirit and scope of the disclosure. Thus, it is intended to contain these modifications and variations in the disclosure if these modifications and variations fall within the scope of the claim and the equivalent thereof.

What is claimed is:

1. A shift register unit, comprising:
a pull-up control module which is adapted to output a pull-up control signal to a pull-up node according to a transmission signal inputted from a transmission signal input terminal, and the pull-up node is on a wire connecting the pull-up control module and the pull-up module;
a pull-up module which is adapted to provide a transmission signal output terminal with a first clock signal inputted from a first clock signal input terminal according to the pull-up control signal, and provide a gate drive signal output terminal with a first direct current supply voltage according to the pull-up control signal and the first clock signal;
a pull-down control module which is adapted to output a pull-down control signal to a pull-down node according to the first clock signal, and the pull-down node is on a wire connecting the pull-down control module and the pull-down module; and
a pull-down module which is adapted to provide the pull-up node, the transmission signal output terminal and the gate drive signal output terminal with a second direct current supply voltage according to the pull-down control signal, a reset signal inputted from a reset signal input terminal and a second clock signal inputted from a second clock signal input terminal; and the first clock signal inputted from the first clock signal input terminal and the second clock signal inputted from the second clock signal input terminal are opposite in phase.

2. The shift register unit according to claim 1, wherein the pull-down module comprises:
a first pull-down sub-module adapted to output the second direct current supply voltage to the pull-up node according to the pull-down control signal and the reset signal;
a second pull-down sub-module adapted to output the second direct current supply voltage to the gate drive signal output terminal according to the second clock signal inputted from the second clock signal input terminal; and
a third pull-down sub-module adapted to output the second direct current supply voltage to the transmission signal output terminal according to the second clock signal inputted from the second clock signal input terminal.

3. The shift register unit according to claim 2, wherein
the first pull-down sub-module comprises a second transistor and an eighth transistor; the second pull-down sub-module comprises an eleventh transistor; the third pull-down sub-module comprises a ninth transistor;
the second transistor has a gate electrode connected to the reset signal input terminal, a source electrode connected to the pull-up node, and a drain electrode connected to the second direct current supply voltage;
the eighth transistor has a gate electrode connected to the pull-down node, a source electrode connected to the pull-up node, and a drain electrode connected to the second direct current supply voltage;
the eleventh transistor has a gate electrode connected to the second clock signal input terminal, a source electrode connected to the gate drive signal output terminal, and a drain electrode connected to the second direct current supply voltage; and
the ninth transistor has a gate electrode connected to the second clock signal input terminal, a source electrode connected to the transmission signal output terminal, and a drain electrode connected to the second direct current supply voltage.

4. The shift register unit according to claim 1, wherein the pull-down module comprises:
a first pull-down sub-module adapted to output the second direct current supply voltage to the pull-up node according to the pull-down control signal and the reset signal;
a second pull-down sub-module adapted to output the second direct current supply voltage to the gate drive signal output terminal according to the second clock signal inputted from the second clock signal input terminal and the reset signal; and
a third pull-down sub-module adapted to output the second direct current supply voltage to the transmission signal output terminal according to the second clock signal inputted from the second clock signal input terminal.

5. The shift register unit according to claim 4, wherein
the first pull-down sub-module comprises a second transistor and an eighth transistor; the second pull-down sub-module comprises a tenth transistor and an eleventh transistor; the third pull-down sub-module comprises a ninth transistor;
the second transistor has a gate electrode connected to the reset signal input terminal, a source electrode connected to the pull-up node, and a drain electrode connected to the second direct current supply voltage;
the eighth transistor has a gate electrode connected to the pull-down node, a source electrode connected to the pull-up node, and a drain electrode connected to the second direct current supply voltage;
the tenth transistor has a gate electrode connected to the reset signal input terminal, a source electrode connected to the gate drive signal output terminal, and a drain electrode connected to the second direct current supply voltage;
the eleventh transistor has a gate electrode connected to the second clock signal input terminal, a source electrode connected to the gate drive signal output terminal, and a drain electrode connected to the second direct current supply voltage; and
the ninth transistor has a gate electrode connected to the second clock signal input terminal, a source electrode connected to the transmission signal output terminal, and a drain electrode connected to the second direct current supply voltage.

6. The shift register unit according to claim 5, wherein
a ratio of a channel width of the tenth transistor to a channel width of the eleventh transistor is 9:1.

7. The shift register unit according to claim 1, wherein the pull-up module comprises:
a capacitor having a first electrode connected to the pull-up node, and a second electrode connected to the transmission signal output terminal;
a sixth transistor having a gate electrode connected to the pull-up node, a source electrode connected to the first clock signal input terminal, and a drain electrode connected to the transmission signal output terminal; and
a third transistor having a gate electrode connected to the pull-up node, a source electrode connected to the first direct current supply voltage, and a drain electrode connected to the gate drive signal output terminal.

8. The shift register unit according to claim 2, wherein the pull-up module comprises:
a capacitor having a first electrode connected to the pull-up node, and a second electrode connected to the transmission signal output terminal;
a sixth transistor having a gate electrode connected to the pull-up node, a source electrode connected to the first clock signal input terminal, and a drain electrode connected to the transmission signal output terminal; and
a third transistor having a gate electrode connected to the pull-up node, a source electrode connected to the first direct current supply voltage, and a drain electrode connected to the gate drive signal output terminal.

9. The shift register unit according to claim 4, wherein the pull-up module comprises:
a capacitor having a first electrode connected to the pull-up node, and a second electrode connected to the transmission signal output terminal;
a sixth transistor having a gate electrode connected to the pull-up node, a source electrode connected to the first clock signal input terminal, and a drain electrode connected to the transmission signal output terminal; and
a third transistor having a gate electrode connected to the pull-up node, a source electrode connected to the first direct current supply voltage, and a drain electrode connected to the gate drive signal output terminal.

10. The shift register unit according to claim 1, wherein the pull-down control module comprises:
a fourth transistor having a gate electrode connected to the first clock signal input terminal, a source electrode connected to the first clock signal input terminal, and a drain electrode connected to the gate electrode of a fifth transistor;
the fifth transistor having a source electrode connected to the first clock signal input terminal, and a drain electrode connected to the pull-down node; and
a seventh transistor having a gate electrode connected to the pull-up node, a source electrode connected to the pull-down node, and a drain electrode connected to the second direct current supply voltage.

11. The shift register unit according to claim 1, wherein the pull-up control module comprises:
a first transistor having a gate electrode connected to the transmission signal input terminal, a source electrode connected to the first direct current supply voltage, and a drain electrode connected to the pull-up node.

12. A gate drive circuit, comprising a plurality of shift register units each comprising:
a pull-up control module which is adapted to output a pull-up control signal to a pull-up node according to a transmission signal inputted from a transmission signal input terminal, and the pull-up node is on a wire connecting the pull-up control module and the pull-up module;
a pull-up module which is adapted to provide a transmission signal output terminal with a first clock signal inputted from a first clock signal input terminal according to the pull-up control signal, and provide a gate drive signal output terminal with a first direct current supply voltage according to the pull-up control signal and the first clock signal;
a pull-down control module which is adapted to output a pull-down control signal to a pull-down node according to the first clock signal, and the pull-down node is on a wire connecting the pull-down control module and the pull-down module; and
a pull-down module which is adapted to provide the pull-up node, the transmission signal output terminal and the gate drive signal output terminal with a second direct current supply voltage according to the pull-down control signal, a reset signal inputted from a reset signal input terminal and a second clock signal inputted from a second clock signal input terminal; and the first clock signal inputted from the first clock signal input terminal and the second clock signal inputted from the second clock signal input terminal are opposite in phase,
wherein except for a first shift register unit and a last shift register unit, each shift register unit has its transmission signal output terminal connected to the reset signal input terminal of a previous shift register unit adjacent to this shift register unit and the transmission signal input terminal of a next shift register unit adjacent to this shift register unit, gate drive signals outputted from the gate drive signal output terminals of the shift register units are outputted from the gate drive circuit in sequence;
the transmission signal output terminal of the first shift register unit is connected to a transmission signal input terminal of a second shift register unit, the transmission signal output terminal of the last shift register unit is connected to the reset signal input terminal of a previous shift register unit adjacent to the last shift register unit; and
a frame start signal is inputted from the transmission signal input terminal of the first shift register unit.

13. The gate drive circuit according to claim 12, wherein the pull-down module comprises:
a first pull-down sub-module adapted to output the second direct current supply voltage to the pull-up node according to the pull-down control signal and the reset signal;
a second pull-down sub-module adapted to output the second direct current supply voltage to the gate drive signal output terminal according to the second clock signal inputted from the second clock signal input terminal; and
a third pull-down sub-module adapted to output the second direct current supply voltage to the transmission signal output terminal according to the second clock signal inputted from the second clock signal input terminal.

14. The gate drive circuit according to claim 13, wherein
the first pull-down sub-module comprises a second transistor and an eighth transistor; the second pull-down sub-module comprises an eleventh transistor; the third pull-down sub-module comprises a ninth transistor;
the second transistor has a gate electrode connected to the reset signal input terminal, a source electrode connected to the pull-up node, and a drain electrode connected to the second direct current supply voltage;
the eighth transistor has a gate electrode connected to the pull-down node, a source electrode connected to the pull-up node, and a drain electrode connected to the second direct current supply voltage;
the eleventh transistor has a gate electrode connected to the second clock signal input terminal, a source electrode connected to the gate drive signal output terminal, and a drain electrode connected to the second direct current supply voltage; and
the ninth transistor has a gate electrode connected to the second clock signal input terminal, a source electrode connected to the transmission signal output terminal, and a drain electrode connected to the second direct current supply voltage.

15. The gate drive circuit according to claim 12, wherein the pull-down module comprises:
a first pull-down sub-module adapted to output the second direct current supply voltage to the pull-up node according to the pull-down control signal and the reset signal;
a second pull-down sub-module adapted to output the second direct current supply voltage to the gate drive signal output terminal according to the second clock signal inputted from the second clock signal input terminal and the reset signal; and
a third pull-down sub-module adapted to output the second direct current supply voltage to the transmission signal output terminal according to the second clock signal inputted from the second clock signal input terminal.

16. The gate drive circuit according to claim 15, wherein
the first pull-down sub-module comprises a second transistor and an eighth transistor; the second pull-down sub-module comprises a tenth transistor and an eleventh transistor; the third pull-down sub-module comprises a ninth transistor;
the second transistor has a gate electrode connected to the reset signal input terminal, a source electrode connected to the pull-up node, and a drain electrode connected to the second direct current supply voltage;
the eighth transistor has a gate electrode connected to the pull-down node, a source electrode connected to the pull-up node, and a drain electrode connected to the second direct current supply voltage;
the tenth transistor has a gate electrode connected to the reset signal input terminal, a source electrode connected to the gate drive signal output terminal, and a drain electrode connected to the second direct current supply voltage;
the eleventh transistor has a gate electrode connected to the second clock signal input terminal, a source electrode connected to the gate drive signal output terminal, and a drain electrode connected to the second direct current supply voltage; and
the ninth transistor has a gate electrode connected to the second clock signal input terminal, a source electrode connected to the transmission signal output terminal, and a drain electrode connected to the second direct current supply voltage.

17. The gate drive circuit according to claim 16, wherein
a ratio of a channel width of the tenth transistor to a channel width of the eleventh transistor is 9:1.

18. The gate drive circuit according to claim 12, wherein the pull-up module comprises:
a capacitor having a first electrode connected to the pull-up node, and a second electrode connected to the transmission signal output terminal;
a sixth transistor having a gate electrode connected to the pull-up node, a source electrode connected to the first clock signal input terminal, and a drain electrode connected to the transmission signal output terminal; and
a third transistor having a gate electrode connected to the pull-up node, a source electrode connected to the first direct current supply voltage, and a drain electrode connected to the gate drive signal output terminal.

19. A display device, comprising the gate drive circuit, wherein the gate drive circuit comprises a plurality of shift register units each comprising:
a pull-up control module which is adapted to output a pull-up control signal to a pull-up node according to a transmission signal inputted from a transmission signal input terminal, and the pull-up node is on a wire connecting the pull-up control module and the pull-up module;
a pull-up module which is adapted to provide a transmission signal output terminal with a first clock signal inputted from a first clock signal input terminal according to the pull-up control signal, and provide a gate drive signal output terminal with a first direct current supply voltage according to the pull-up control signal and the first clock signal;
a pull-down control module which is adapted to output a pull-down control signal to a pull-down node according to the first clock signal, and the pull-down node is on a wire connecting the pull-down control module and the pull-down module; and
a pull-down module which is adapted to provide the pull-up node, the transmission signal output terminal and the gate drive signal output terminal with a second direct current supply voltage according to the pull-down control signal, a reset signal inputted from a reset signal input terminal and a second clock signal inputted from a second clock signal input terminal; and the first clock signal inputted from the first clock signal input terminal and the second clock signal inputted from the second clock signal input terminal are opposite in phase,
wherein except for a first shift register unit and a last shift register unit, each shift register unit has its transmission signal output terminal connected to the reset signal input terminal of a previous shift register unit adjacent to this shift register unit and the transmission signal input terminal of a next shift register unit adjacent to this shift register unit, gate drive signals outputted from the gate drive signal output terminals of the shift register units are outputted from the gate drive circuit in sequence;
the transmission signal output terminal of the first shift register unit is connected to a transmission signal input terminal of a second shift register unit, the transmission signal output terminal of the last shift register unit is connected to the reset signal input terminal of a previous shift register unit adjacent to the last shift register unit; and
a frame start signal is inputted from the transmission signal input terminal of the first shift register unit.

20. The display device according to claim 19, wherein the display device comprises at least one of a liquid crystal panel, an electronic paper, a liquid crystal TV, a liquid crystal display (LCD), a digital photo frame, a mobile phone, a tablet computer, and an outdoor display.
